(19) United States
(12) Patent Application Publication
(10) Pub. No.: US 2021/0216876 A1
(43) Pub. Date: Jul. 15, 2021

(54) SYSTEMS AND METHODS FOR AUTO-ENCODER BEHAVIOR MODELLING OF VEHICLE COMPONENTS

(71) Applicants: TOYOTA MOTOR ENGINEERING & MANUFACTURING NORTH AMERICA, INC., Plano, TX (US); UNIVERSITY OF CONNECTICUT, Farmington, CT (US)

(72) Inventors: Donald McMenemy, Willington, CT (US); John Kaminski, Vernon, CT (US); Shailesh N. Joshi, Ann Arbor, MI (US); Ali M. Bazzi, South Windsor, CT (US); Krishna Pattipati, Storrs Mansfield, CT (US)

(73) Assignees: TOYOTA MOTOR ENGINEERING & MANUFACTURING NORTH AMERICA, INC., PLANO, TX (US); UNIVERSITY OF CONNECTICUT, FARMINGTON, CT (US)

(21) Appl. No.: 16/743,578

(22) Filed: Jan. 15, 2020

(51) Int. Cl. G06N 3/08

(52) U.S. Cl. CPC G06N 3/088; G06F 30/20

(57) ABSTRACT

Systems and methods of auto-encoder behavior modelling of vehicle components are described herein. A method for electronic device health prediction may include encoding input data into a reduced feature set via an auto-encoder as part of an artificial neural network. The method may further include decoding the reduced feature set. The method may also include reading the reduced feature set as output. The method may still further include encoding features of a subject device and other devices, wherein at least one of the other devices is designated as a healthy device. The method may additionally include associating the features of the other devices with a healthy device cluster based on a threshold distance. The method may also additionally include associating the features of the subject device with the healthy device cluster, wherein the subject device is flagged as faulty based upon exceeding the threshold distance from the healthy device cluster.

### TECHNICAL FIELD

The present application generally relates to artificial neural networks and, more particularly, to auto-encoders used to model vehicle component behaviors.

### BACKGROUND

Power electronics modules, such as those used in electric vehicles, typically operate at high power densities and in high temperature conditions. Thus, power electronics modules experience a degradation or aging process. Basic sensor output data involving module current and voltage, plus device temperature, can be utilized to detect anomalies (e.g., bond wire failure, die attach failure, substrate delamination, etc.), thus predicting the failure of the power electronics modules. It can be difficult, however, to determine which power electronics modules may be faulty during production as well as those near failure in the field.

### SUMMARY

In one aspect, a method for electronic device health prediction may include encoding input data into a reduced feature set via an auto-encoder as part of an artificial neural network. The method may further include decoding the reduced feature set. The method may also include reading the reduced feature set as output. The method may still further include encoding features of a subject device and other devices, wherein at least one of the other devices is designated as a healthy device. The method may additionally include associating the features of the other devices with a healthy device cluster based on a threshold distance. The method may also additionally include associating the features of the subject device with the healthy device cluster, wherein the subject device is flagged as faulty based upon exceeding the threshold distance from the healthy device cluster.

In another aspect, an electronic device health prediction system may include non-transitory memory and a processor coupled to the non-transitory memory. The system may further include an artificial neural network comprising an auto-encoder configured to utilize the processor to encode input data into a reduced feature set. The auto-encoder may be further configured to decode the reduced feature set. The auto-encoder may also be configured to read the reduced feature set as output. The system may also include a testing module configured to encode features of a subject device and other devices, wherein at least one of the other devices is designated as a healthy device. The testing module may be further configured to associate the features of the other devices with a healthy device cluster based on a threshold distance. The testing module may be additionally configured to associate the features of the subject device with the healthy device cluster, wherein the subject device exceeding a threshold distance from the cluster of healthy devices is flagged as faulty.

In yet another aspect, an electronic device health prediction system may include non-transitory memory and a processor coupled to the non-transitory memory. The system may further include an artificial neural network comprising an auto-encoder configured to utilize the processor to receive a multi-dimensional input feature set of three or more dimensions. The auto-encoder may be configured to record a median value for each of the dimensions based upon a plurality of times when the subject device is on. The auto-encoder may be additionally configured to encode input data into a reduced feature set. The auto-encoder may be further configured to decode the reduced feature set. The auto-encoder may also be configured to read the reduced feature set as output. The system may also include a testing module configured to encode features of a subject device and other devices, wherein at least one of the other devices is designated as a healthy device. The testing module may be further configured to associate the features of the other devices with a healthy device cluster based on a Mahalanobis distance. The testing module may also be additionally configured to determine which of the other device clusters the subject device is most similar, based upon respective distances of the subject device to each of the device clusters within the reduced feature set. The testing module may also be additionally configured to associate the features of the subject device with the healthy device cluster, wherein the subject device having a Mahalanobis distance exceeding a threshold distance from the cluster of healthy devices is flagged as faulty.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1A is a block diagram illustrating an exemplary system for an auto encoder training phase, according one or more embodiments shown and described herein;

FIG. 1B is a block diagram illustrating an exemplary system for an auto encoder testing phase, according one or more embodiments shown and described herein;

FIG. 2 is a diagram schematically illustrating an exemplary auto encoding process utilizing K-means to cluster the training set features observed in the encoded features, according one or more embodiments shown and described herein;

FIG. 3 is a diagram schematically illustrating an exemplary auto encoding process utilizing K-means to test new observed features in another device where the health is unknown, according one or more embodiments shown and described herein;

FIG. 4 is an exemplary graph illustrating observed operating points for a device as a function of cycling the load resistance or duty cycle when the device is operating, according one or more embodiments shown and described herein;

FIG. 5 is an exemplary graph illustrating on-state resistance of an example power electronics device and the exponentially weighted moving average of the resistance, according one or more embodiments shown and described herein;

FIG. 6A is an exemplary graph illustrating the principal component analysis of the on-state resistance of an exemplary power electronics device in T² statistics, according one or more embodiments shown and described herein;

FIG. 6B is an exemplary graph illustrating the principal component analysis of the on-state resistance of an exemplary power electronics device in Q statistics, according one or more embodiments shown and described herein;

FIG. 7A is an exemplary graph illustrating the exponentially weighted moving average of the on-state resistance of an exemplary power electronics device in T² statistics, according one or more embodiments shown and described herein;

FIG. 7B is an exemplary graph illustrating the exponentially weighted moving average of the on-state resistance of an exemplary power electronics device in Q statistics, according one or more embodiments shown and described herein;

FIG. 8 illustrates a flowchart for visual clustering for outlier detection, according to one or more embodiments described and illustrated herein;

FIG. 9 illustrates a flowchart for an exponentially weighted moving average autoencoder for anomaly detection, according to one or more embodiments described and illustrated herein;

FIG. 10 illustrates a flowchart for exponentially weighted moving average principal component analysis for anomaly detection, according to one or more embodiments described and illustrated herein; and

FIG. 11 is a block diagram illustrating computing hardware utilized in one or more devices for implementing various systems and processes, according one or more embodiments shown and described herein.

### DETAILED DESCRIPTION

Embodiments of the present disclosure are directed to predicting power electronic device failure utilizing an autoencoder with a neural network to encode input data into a reduced feature set. Specifically, a training phase may be used to train the neural network to recognize healthy device behavior, including the drift in the operating point of healthy devices over time. Device behavior may be modeled using clusters of devices, where the Mahalanobis distance between a given device and various clusters may be used to learn healthy versus unhealthy device behaviors over time. A testing phase may then be used to analyze a given device to determine whether the device is more closely associated with a cluster of healthy devices or a cluster unhealthy devices. A device may be a vehicle power device, which may include a semiconductor switching device. Non-limiting examples may include insulated gate bipolar transistors, power transistors, bipolar mode static induction transistors, power MOSFETs, and the like.

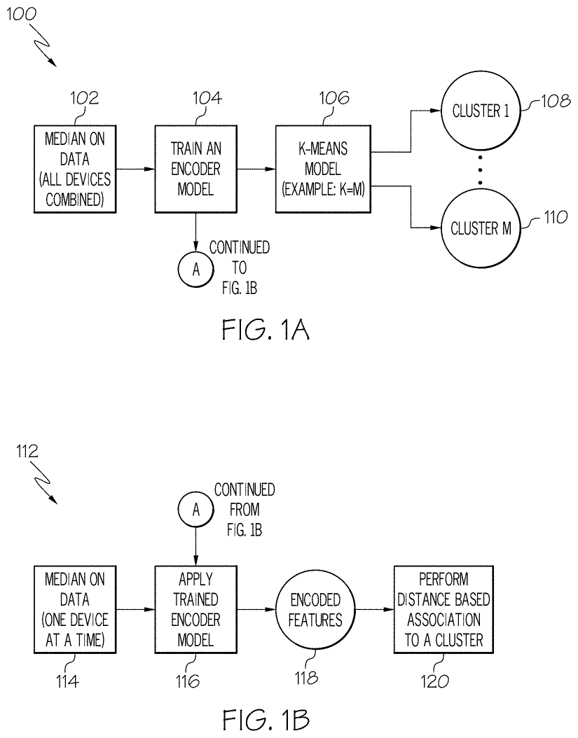

Turning to FIG. 1A, an autoencoder training phase 100 is depicted in an embodiment featuring an autoencoder (i.e., an unsupervised artificial neural network), which, as discussed further herein, utilizes an encoder and a decoder. Training median data 102 may feature the median “on data” pertaining to the behavior of devices being powered on within a data set of any suitable size. In one example, this may involve recording a median value for each of the dimensions associated with the device based upon measurements obtained from a plurality of times when the device is on. This may further involve receiving the median value for each of the dimensions to produce a two dimensional space, as discussed in more detail herein. The training median data 102 utilizes the median of all devices combined. Encoder model training 104, as discussed in more detail herein, is used to generate a model utilized in the device testing phase (proceeding to step A proceeding from 104 in FIG. 1A to 116 in FIG. 1B).

In this embodiment, the encoder maps data to a dimensionally-reduced space, while the decoder reproduces a representation of the original data obtained from the encoded, dimensionally-reduced space. Utilizing the trained encoder, a k-means model 106 is used to cluster the training data into a first cluster 108 and additional clusters 110, where the clustering, as discussed in more detail, is based upon observed encoded device features in the dimensionally-reduced training set. This may involve, for example, clustering training set features observed in the encoded features according to K-means clustering. In this way, the good behavior of devices can be modeled using the encoded space of an autoencoder by plotting the encoded features against one another and observing where the patterns of good behavior lie in the training phase.

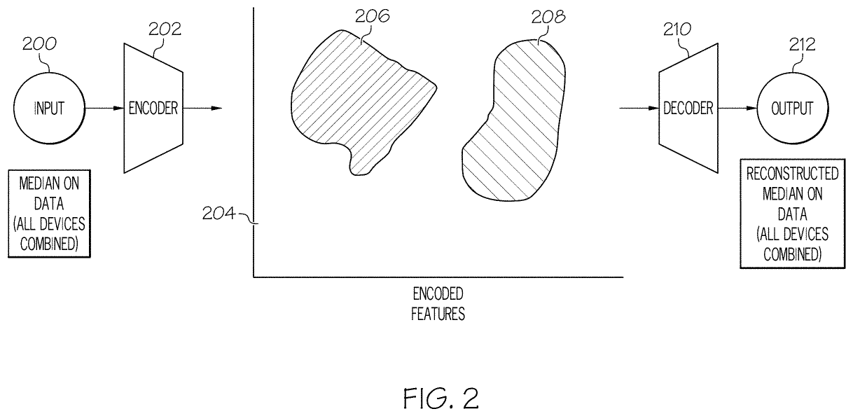

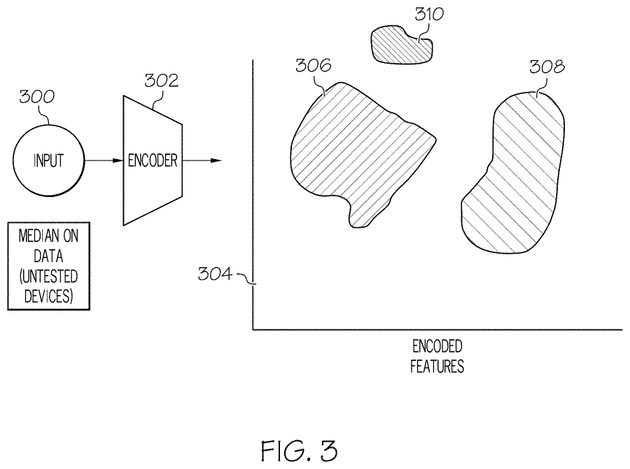

Turning to FIG. 1B, an autoencoder testing phase 112 is depicted in an embodiment utilizing a trained model. In this embodiment, testing median on data 114 is received/input on a per-device basis, rather than combined as in the training phase 100. Once the training phase 100 is complete (see step A proceeding from 104 in FIG. 1A) and the model has been developed, the trained encoder model 116 is applied to the testing median on data 114. The trained encoder model 116 encodes the data into a dimensionally-reduced space based upon encoded features by applying the trained model 116 learned in a training phase 100 to encode features of the other devices and associate the features of the other devices. For example, if a device is represented by an input feature set of three or more dimensions, the encoder may be used to reduce the representation of each device within a two dimensional space based upon two preselected dimensions. Dimensions may be any suitable characteristics that can pertain to devices. Non-limiting examples of dimensions can include diode temperature, case to heat-sink temperature difference, voltage drain to source, current drain to source, voltage gate to source, power, and/or estimated thermal resistance. As discussed in more detail in FIGS. 2-3, distance-based cluster association 120 is performed utilizing the encoded features 118 as pertaining to the dimensionally-reduced representations of the devices within the testing median on data 114.

Turning to FIG. 2, an exemplary auto encoding process utilizes K-means to cluster the training set features observed in the encoded features. Median data pertaining to median on-state data of all devices combined serves as input 200 for an encoder as part of an autoencoder. Any suitable type of encoder may be utilized. Within the dimensionally-reduced encoded space 204, K-means clustering is utilized to place devices in the training phase into a first cluster 206 and a second cluster 208, although any suitable clustering or other organizational technique may be utilized. K-means clustering utilizes vector quantization, where, as discussed herein, each device is assigned a vector label. The vectors are grouped into clusters based upon their respective positions relative to the mean of each cluster (i.e., the cluster prototype value). As discussed herein, the cluster grouping may be based, for example, on determining a minimum Mahalanobis distance between the mean of each cluster and the location of the vector label, thus associating the device with the behavior of a cluster whose behavior most closely resembles that of the device. A Mahalanobis distance is a measurement of how many standard deviations away a particular point is from the mean of a cluster or other distribution.

A decoder 210 is utilized to output 212 the reconstructed median on data (of all devices combined) by mapping the clustered, dimensionally reduced representations back to a reconstruction of their original form. This preserves only relevant aspects of the input 200 in the output 212. Any suitable type of decoder 210 may be utilized to output 212 the reconstructed median on data (of all devices combined) that corresponds to the input 200.

Turning to FIG. 3, an exemplary auto encoding process utilizes K-means to test new observed features in another device where the health is unknown. Input 300 in this embodiment pertains to untested devices whose median on data is input into the encoder 302 to produce a dimensionally-reduced encoded space 204 of two dimensions. Based upon the input 300, a first cluster 306, a second cluster 308, and a third cluster 310 are generated. For example, if the third cluster 310 is a “healthy cluster” (i.e., exhibits healthy behavior), then the Mahalanobis distance with respect to the third cluster 310 can serve as a threshold indicator of device failure if it deviates from all healthy clusters. Device failure can also be associated with adhering most closely to a “bad” cluster of devices experiencing or on the verge of failure.

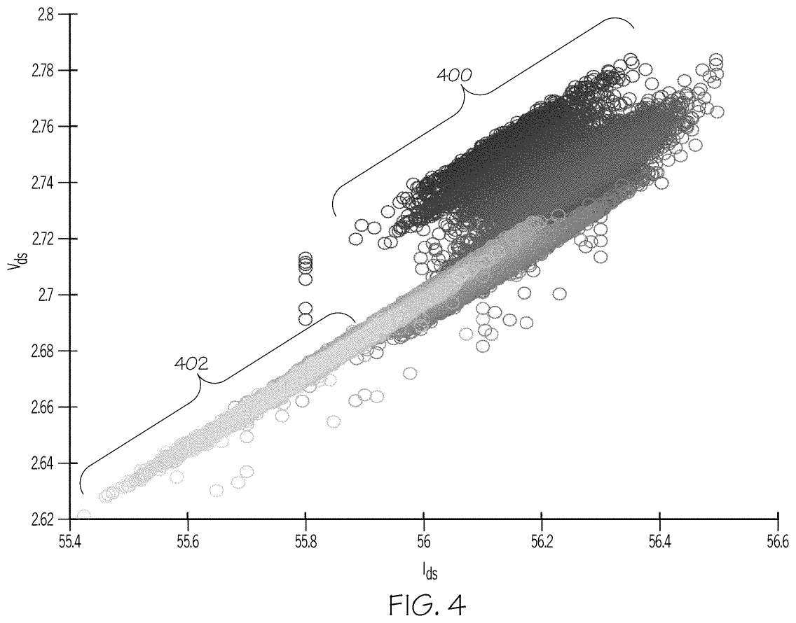

Turning to FIG. 4, an exemplary graph illustrates observed operating points for a device as a function of cycling a load resistance or duty cycle when the device is operating. The observed operating points for a device are represented as a function of cycling current (I_{ds}) and voltage drain to source (V_{ds}) when the device is operating (i.e., the “on state”). The darker data points (i.e., circles) correspond to the beginning of the time series 400, while the lighter data points represent the data from the end of the time series 402. As shown in FIG. 4, the device experiences an operating drift over time. However, this does not indicate an imminent device fault, which is observed when there are discontinuities in the features (given the devices have not been turned on). For example, the mean of the distributions is updated to account for the healthy operation of the observed measurements drifting under accelerated aging tests. In this embodiment, a continuous change in on-state resistance of the subject device is not indicative of a failure, whereas an imminent fault based upon discontinuities in features above a threshold before the subject device is powered on.

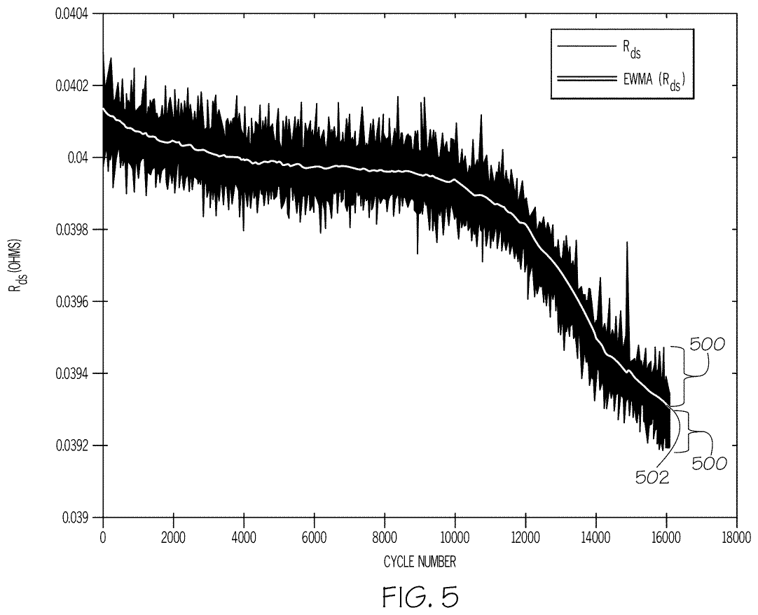

Turning to FIG. 5, an exemplary graph illustrates on-state resistance (R_{ds}) 500 of an example power electronics device and the exponentially weighted moving average 502 of the resistance. The exponentially weighted moving average assigns greater weight to more recent data points and diminishes prior observations as they increase in age. The R_{ds} 500 and the exponentially weighted moving average 502 are plotted over thousands of power cycles, where there is a noticeable decline in R_{ds} 500 and the exponentially weighted moving average 502. However, this continuous change in R_{ds} 500 is not indicative of a failure, as the device's operation point is non-stationary. As discussed previously with respect to FIGS. 2-3, healthy device behavior can be modeled to account for non-stationary (i.e., drifting) behavior. By contrast, disjointed data points that fall outside of the general drift could be indicative of imminent device failure.

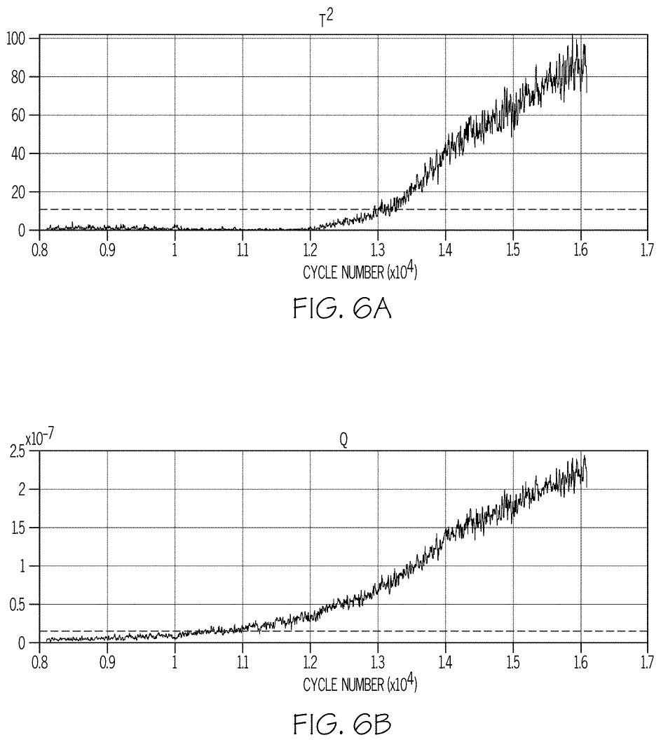

Turning to FIG. 6A, an exemplary graph in T² statistics illustrates the principal component analysis of R_{ds} of an exemplary power electronics device. In contrast to the exponentially weighted moving average, more training data is used here with principal component analysis for the training phase of the artificial neural network.

Turning to FIG. 6B, an exemplary graph in Q statistics illustrates the principal component analysis of R_{ds} of an exemplary power electronics device. In contrast to the exponentially weighted moving average, more training data is used here with principal component analysis for the training phase of the artificial neural network.

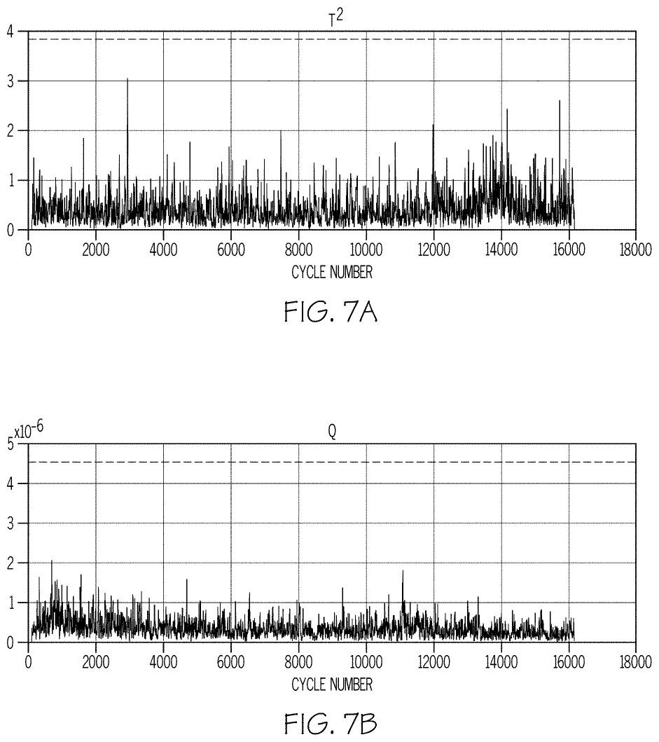

Turning to FIG. 7A, an exemplary graph in T² statistics illustrates the exponentially weighted moving average of R_{ds} of an exemplary power electronics device. In contrast to the T² statistics illustration of FIG. 6A, less training data is used here for the training phase of the artificial neural network by utilizing the exponentially weighted moving average.

Turning to FIG. 7B, an exemplary graph in Q statistics illustrates the exponentially weighted moving average of R_{ds} of an exemplary power electronics device. In contrast to the Q statistics illustration of FIG. 6B, less training data is used here for the training phase of the artificial neural network by utilizing the exponentially weighted moving average.

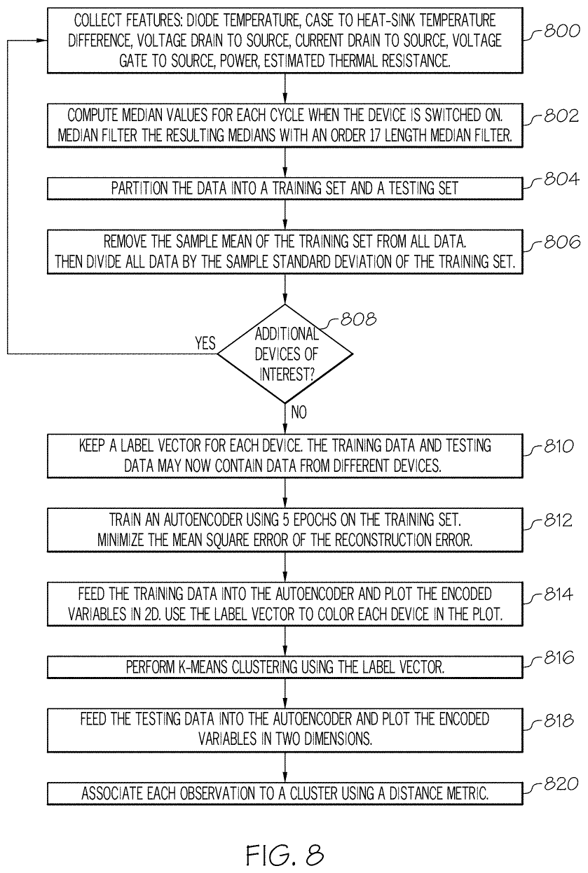

Turning to FIG. 8, a flowchart depicts an exemplary process of visual clustering for outlier detection. At block 800, device features may be collected. Features of devices, by way of non-limiting example, may include one or more of diode temperature, case to heat-sink temperature difference, voltage drain to source, current drain to source, voltage gate to source, power, and/or estimated thermal resistance. Collection of these features may be performed, for example, by electrical current injection and/or measurement devices, devices that measure electrical resistance such as ohmmeters and multimeters, and thermal sensors such as diode temperature sensors. In other embodiments, any other suitable device features may be utilized. At block 802, median values are computed for each cycle when the device is switched on. In some embodiments, a device may subject to any suitable number of cycles, which may include accelerated aging to simulate device degradation over time. Thus, the mean of the moving distribution can be updated to account for observed measurements drifting under accelerated aging tests within healthy operation. A median-filter may be performed upon the resulting medians. In this example, this is with an order 17 length median-filter, although any suitable order length median-filter may be utilized.

At block 804, the data is partitioned into a training set and a testing set. Specifically, some of the data regarding the computed median values for each device cycle can be used as a training set so that the model learns healthy device behavior, including any drift in operating points over time. Other portions of the computed median values data can be used in the testing phase to determine whether a given device is exhibiting healthy device behavior. The data used for testing is not used to modify the trained model. A sample mean is also applied to the training set as an estimator for the population mean of the training set. At block 806, the sample mean of the training set is removed. All of the data is then divided by the sample standard deviation of the training set.

At block 808, a determination is made as to whether there are additional devices of interest. Additional devices, which may be other power devices similar to the current device of interest, may be in the testing dataset, such that the determination hinges upon whether there are any additional devices remaining in the testing dataset. If additional devices of interest are available, then the process returns to block 800. Otherwise, if no additional devices of interest are available, then at block 810, a label vector for may be kept or applied to each device within the training data and/or testing data. The training data and testing data may now contain data from respectively different devices. At block 812, an autoencoder may be trained using, for example, 5 epochs on the training set. An epoch may relate in this example to intervals of power-cycling the device. Any suitable number of epochs may be utilized. During reconstruction of the training data within a reduced-dimensionality data set, the mean square error of the reconstruction error is minimized. The mean square error estimates the unobserved quantity of the training data, for example, and measures the average squared difference between the estimated and actual values.

At block 814, the training data is provided as input into the encoder portion of the autoencoder for dimensionality reduction. Specifically, the training data is encoded utilizing variables in two dimensions. For example, the training data may be represented by four dimensions, and is then encoded to be reduced to two dimensions. Dimensionality reduction may be accomplished by any suitable technique, such as feature selection or feature projection (e.g., principle component analysis, kernel principle component analysis, non-negative matrix factorization, graph-based kernel principle component analysis, linear discriminant analysis, generalized discriminant analysis, and the like). The label vector that represents a given device may be plotted in the reduced two dimensional space. In this example, the label vectors may be represented by a color applied each device plotted in the two dimensional space. At block 816, k-means clustering is performed using the label vectors representing individual devices in the training data. As discussed with respect to FIGS. 2-3, the device clusters are color-coded to make them distinct. At block 818, once the training of the autoencoder is complete and a model has been generated, the testing data is fed into the autoencoder as input. Similar to the training data, the encoded variables are plotted in two dimensions with respect to each device in the testing phase. At block 820, each observation is associated with a cluster using a distance metric, such as the Mahalanobis distance between a label vector representing a device and the mean (or other representation) of a cluster (or other distribution).

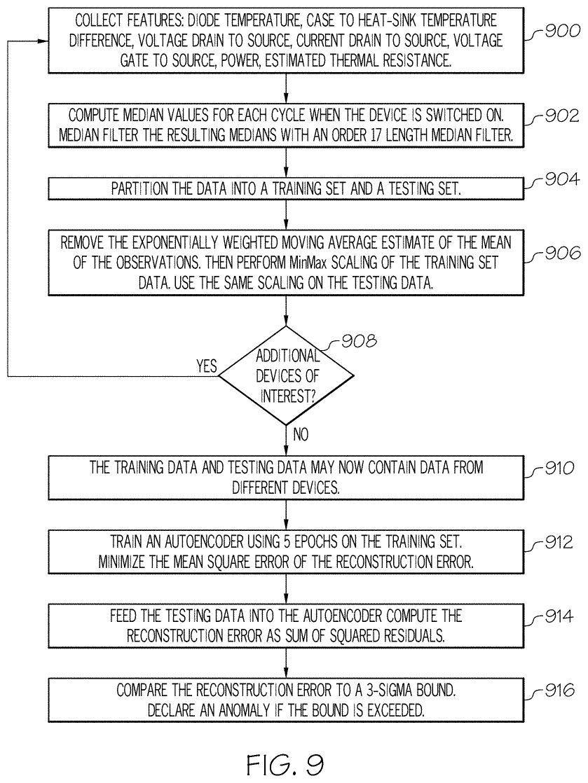

Turning to FIG. 9, a flowchart depicts an exemplary process of anomaly detection utilizing an exponentially weighted moving average autoencoder. At block 900, device features may be collected. Features of devices, by way of non-limiting example, may include one or more of diode temperature, case to heat-sink temperature difference, voltage drain to source, current drain to source, voltage gate to source, power, and/or estimated thermal resistance. Collection of these features may be performed, for example, by electrical current injection and/or measurement devices, devices that measure electrical resistance such as ohmmeters and multimeters, and thermal sensors such as diode temperature sensors. In other embodiments, any other suitable device features may be utilized. At block 902, median values are computed for each cycle when the device is switched on. In some embodiments, a device may subject to any suitable number of cycles, which may include accelerated aging to simulate device degradation over time. A median-filter may be performed upon the resulting medians. In this example, this is with an order 17 length median-filter, although any suitable order length median-filter may be utilized.

At block 904, the data is partitioned into a training set and a testing set. Specifically, some of the data regarding the computed median values for each device cycle can be used as a training set so that the model learns healthy device behavior, including any drift in operating points over time. Other portions of the computed median values data can be used in the testing phase to determine whether a given device is exhibiting healthy device behavior. The data used for testing is not used to modify the trained model. A sample mean is also applied to the training set as an estimator for the population mean of the training set. At block 906, exponentially weighted moving average estimate of the mean of the observations is removed. Specifically, the exponentially weighted moving average estimate of the mean pertains to an estimate of how the movement of behavior of devices was initially predicted to behave. Once the exponentially weighted moving average estimate of the mean has been removed, then MinMax scaling is performed of the training set data. MinMax rescaling is a type of feature scaling that rescales a range of features to scale the range (such as [0, 1] or [−1, 1]). The target range selected may depend on the nature of the data.

At block 908, a determination is made as to whether there are additional devices of interest. Additional devices, which may be other power devices similar to the current device of interest, may be in the testing dataset, such that the determination hinges upon whether there are any additional devices remaining in the testing dataset. If additional devices of interest are available, then the process returns to block 800. Otherwise, if no additional devices of interest are available, then at block 910, the training data and testing data may contain data from respectively different devices, and may be mutually exclusive.

At block 912, an autoencoder may be trained using, for example, 5 epochs on the training set. An epoch may relate in this example to intervals of power-cycling the device. Any suitable number of epochs may be utilized. During reconstruction of the training data within a reduced-dimensionality data set, the mean square error of the reconstruction error is minimized. At block 914, the testing data is input into the autoencoder, where the reconstruction error is computed the as sum of squared residuals (i.e., the sum of squared estimate of errors) is a measure of discrepancy between the predicted model used in the autoencoder versus the actual measurements. Determining this difference helps the neural network refine its model as it reduces the discrepancy over iterations. At block 916, compare the reconstruction error to a 3-sigma bound (i.e., a calculation that refers to data within three standard deviations from a mean). An anomaly for a device is identified/declared if the 3-sigma bound (e.g., a threshold) is exceeded.

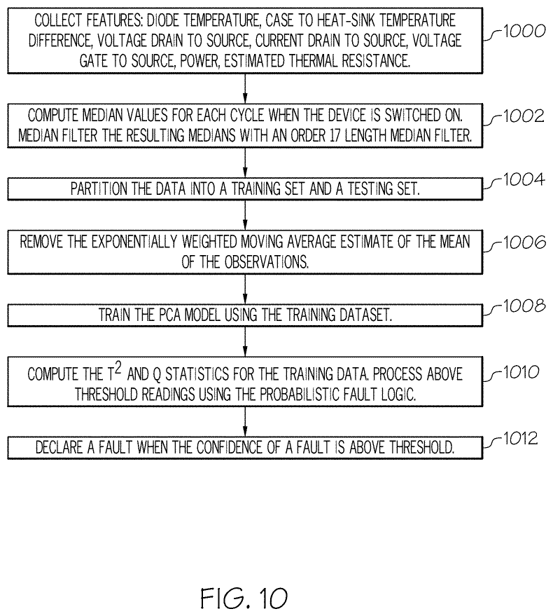

Turning to FIG. 10, a flowchart depicts an exemplary process of anomaly detection utilizing exponentially weighted moving average principal component analysis. At block 1000, device features may be collected. Features of devices, by way of non-limiting example, may include one or more of diode temperature, case to heat-sink temperature difference, voltage drain to source, current drain to source, voltage gate to source, power, and/or estimated thermal resistance. Collection of these features may be performed, for example, by electrical current injection and/or measurement devices, devices that measure electrical resistance such as ohmmeters and multimeters, and thermal sensors such as diode temperature sensors. In other embodiments, any other suitable device features may be utilized. At block 1002, median values are computed for each cycle when the device is switched on. In some embodiments, a device may subject to any suitable number of cycles, which may include accelerated aging to simulate device degradation over time. A median-filter may be performed upon the resulting medians. In this example, this is with an order 17 length median-filter, although any suitable order length median-filter may be utilized.

At block 1004, the data is partitioned into a training set and a testing set. Specifically, some of the data regarding the computed median values for each device cycle can be used as a training set so that the model learns healthy device behavior, including any drift in operating points over time. Other portions of the computed median values data can be used in the testing phase to determine whether a given device is exhibiting healthy device behavior. The data used for testing is not used to modify the trained model. A sample mean is also applied to the training set as an estimator for the population mean of the training set. At block 1006, exponentially weighted moving average estimate of the mean of the observations is removed. Specifically, the exponentially weighted moving average estimate of the mean pertains to an estimate of how the movement of behavior of devices was initially predicted to behave.

At block 1008, principal component analysis model is trained using the training dataset. Principal component analysis utilizes an orthogonal transformation to convert a set of observations about a set of variables whose relations are unknown into a set of values of linearly-uncorrelated variables (principal components). In this embodiment, principal component analysis models the moving distribution and forms the moving distribution from a portion of data observed during a time period when the subject device was in a healthy condition. At block 1010, T² and Q statistics are computed for the training data. As discussed previously, FIGS. 6A and 6B respectively illustrate training data in T² and Q statistics obtained by performing principal component analysis of R_{ds} in power electronics devices. Devices having reading above a threshold, using the probabilistic fault logic (such as fault tree analysis), are identified. At block 1012, a device fault is declared when the confidence of a fault is above a specified threshold.

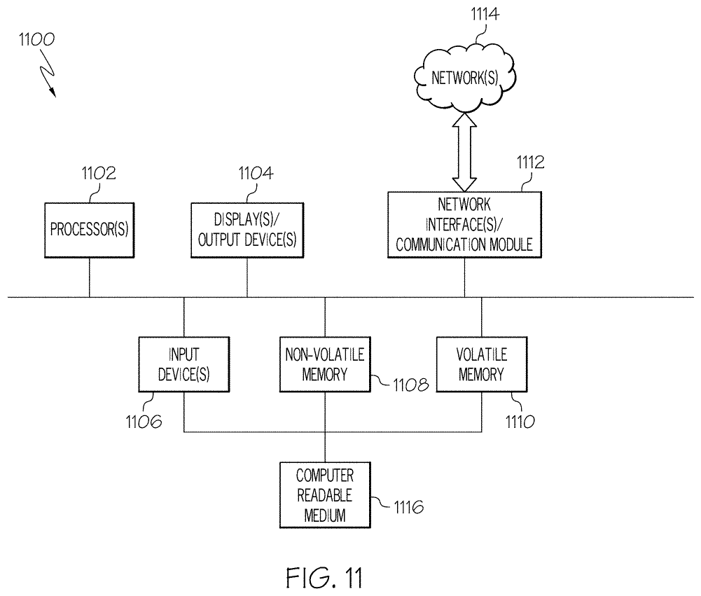

Turning to FIG. 11, a block diagram illustrates an exemplary computing environment 1100 through which embodiments of the disclosure can be implemented, such as, for example, in the encoders 202, 302 and/or decoder 210 as depicted in FIGS. 2-3 and/or any subcomponents therein, along with any other computing device depicted in any of FIGS. 1-10. The exemplary computing environment 1100 may include non-volatile memory 1108 (ROM, flash memory, etc.), volatile memory 1110 (RAM, etc.), or a combination thereof. In some embodiments, the at least one processor 1102 is coupled to non-transitory memory such as the non-volatile memory 1108 and/or volatile memory 1110. The exemplary computing environment 1100 may utilize, by way of non-limiting example, RAM, ROM, cache, fiber optics, EPROM/Flash memory, CD/DVD/BD-ROM, hard disk drives, solid-state storage, optical or magnetic storage devices, diskettes, electrical connections having a wire, any system or device that is of a magnetic, optical, semiconductor, or electronic type, or any combination thereof.

The exemplary computing environment 1100 can include one or more displays and/or output devices 1104 such as monitors, speakers, headphones, projectors, wearable-displays, holographic displays, and/or printers, for example. The exemplary computing environment 1100 may further include one or more input devices 1106 which can include, by way of example, any type of mouse, keyboard, disk/media drive, memory stick/thumb-drive, memory card, pen, joystick, gamepad, touch-input device, biometric scanner, voice/auditory input device, motion-detector, camera, scale, etc.

A network interface 1112 can facilitate communications over one or more networks 1114 via wires, via a wide area network, via a local area network, via a personal area network, via a cellular network, via a satellite network, etc. Suitable local area networks may include wired Ethernet and/or wireless technologies such as, for example, wireless fidelity (Wi-Fi). Suitable personal area networks may include wireless technologies such as, for example, IrDA, Bluetooth, Wireless USB, Z-Wave, ZigBee, and/or other near field communication protocols. Suitable personal area networks may similarly include wired computer buses such as, for example, USB and FireWire. Suitable cellular networks include, but are not limited to, technologies such as LTE, WiMAX, UMTS, CDMA, and GSM. The exemplary computing environment 1100 may include one or more network interfaces 1112 to facilitate communication with one or more remote devices, which may include, for example, client and/or server devices. A network interface 1112 may also be described as a communications module, as these terms may be used interchangeably. Network interface 1112 can be communicatively coupled to any device capable of transmitting and/or receiving data via the one or more networks 1114, which may correspond to any computing device depicted in any of FIGS. 1-10, by way of non-limiting example.

The network interface hardware 1112 can include a communication transceiver for sending and/or receiving any wired or wireless communication. For example, the network interface hardware 1112 may include an antenna, a modem, LAN port, Wi-Fi card, WiMax card, mobile communications hardware, near-field communication hardware, satellite communication hardware and/or any wired or wireless hardware for communicating with other networks and/or devices.

A computer-readable medium 1116 may comprise a plurality of computer readable mediums, each of which may be either a computer readable storage medium or a computer readable signal medium. A computer readable medium 1116 may reside, for example, within an input device 1106, non-volatile memory 1108, volatile memory 1110, or any combination thereof. A computer readable storage medium can include tangible media that is able to store instructions associated with, or used by, a device or system. A computer readable storage medium includes, by way of non-limiting examples: RAM, ROM, cache, fiber optics, EPROM/Flash memory, CD/DVD/BD-ROM, hard disk drives, solid-state storage, optical or magnetic storage devices, diskettes, electrical connections having a wire, or any combination thereof. A computer readable storage medium may also include, for example, a system or device that is of a magnetic, optical, semiconductor, or electronic type. Computer readable storage media exclude propagated signals and carrier waves.

It should now be understood that an autoencoder working with a neural network can produce a reduced feature space derived from healthy power electronics devices for training. In some embodiments, other devices may then be encoded as a reduced feature set and compared to the encoded features of the healthy devices to determine health of other devices. Unlike principle component analysis, which is restricted to a linear map, an autoencoder can utilize nonlinear enoder/decoders for non-linear dimensionality, thus increasing versatility.

Based upon the foregoing, it should be understood that training and testing of an artificial neural network in conjunction with an autoencoder to more accurately diagnose imminent failure in vehicular power devices is not directed towards an abstract idea. In particular, the functioning of the artificial neural network is improved by developing and improving a model over time to be used in the testing phase. Further, the subject matter herein improves the reliability of power devices in vehicles by providing more accurate testing.

It is noted that recitations herein of a component of the present disclosure being “configured” or “programmed” in a particular way, to embody a particular property, or to function in a particular manner, are structural recitations, as opposed to recitations of intended use. More specifically, the references herein to the manner in which a component is “configured” or “programmed” denotes an existing physical condition of the component and, as such, is to be taken as a definite recitation of the structural characteristics of the component.

The order of execution or performance of the operations in examples of the disclosure illustrated and described herein is not essential, unless otherwise specified. That is, the operations may be performed in any order, unless otherwise specified, and examples of the disclosure may include additional or fewer operations than those disclosed herein. For example, it is contemplated that executing or performing a particular operation before, contemporaneously with, or after another operation is within the scope of aspects of the disclosure.

It is noted that the terms “substantially” and “about” and “approximately” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A method for electronic device health prediction comprising:
encoding input data into a reduced feature set via an auto-encoder as part of an artificial neural network;
decoding the reduced feature set;
reading the reduced feature set as output;
encoding features of a subject device and other devices, wherein at least one of the other devices is designated as a healthy device;
associating the features of the other devices with a healthy device cluster based on a threshold distance; and
associating the features of the subject device with the healthy device cluster, wherein the subject device is flagged as faulty based upon exceeding the threshold distance from the healthy device cluster.

2. The method of claim 1 further comprising receiving a multi-dimensional input feature set of three or more dimensions.

3. The method of claim 2 wherein the multi-dimensional input feature set comprises a plurality of diode temperatures, a case to heat-sink temperature difference, a voltage drain to source, a current drain to source, a voltage gate to source, power, and an estimated thermal resistance.

4. The method of claim 2 further comprising recording a median value for each of the dimensions based upon measurements obtained from a plurality of times when the device is on.

5. The method of claim 4 further comprising inputting the median value for each of the dimensions to produce a two dimensional space.

6. The method of claim 1 wherein the threshold distance comprises a Mahalanobis distance.

7. The method of claim 1 further comprising:
utilizing a trained model learned in a training phase to encode features of the other devices and associate the features of the other devices; and
associating the features of the other devices to a cluster found in the training phase based upon respective distances in a plurality of threshold distances.

8. The method of claim 7 further comprising determining which of the device clusters the subject device is most similar, based upon respective distances of the subject device to each of the device clusters within the reduced feature set.

9. The method of claim 7 further comprising clustering training set features observed in the encoded features according to K-means clustering.

10. The method of claim 7 wherein the training phase comprises:
encoding features from testing data, based upon a plurality of times when the subject device is on, by feeding the testing data into the autoencoder; and
plotting the encoded features in two dimensions.

11. An electronic device health prediction system comprising:
non-transitory memory and a processor coupled to the non-transitory memory;
an artificial neural network comprising:
an auto-encoder configured to utilize the processor to:
encode input data into a reduced feature set;
decode the reduced feature set; and
read the reduced feature set as output; and
a testing module configured to:
encode features of a subject device and other devices, wherein at least one of the other devices is designated as a healthy device;
associate the features of the other devices with a healthy device cluster based on a threshold distance; and
associate the features of the subject device with the healthy device cluster, wherein the subject device exceeding a threshold distance from the cluster of healthy devices is flagged as faulty.

12. The electronic device health prediction system of claim 11 wherein the testing module is further configured to receive a multi-dimensional input feature set of three or more dimensions.

13. The electronic device health prediction system of claim 12 wherein the multi-dimensional input feature set comprises a plurality of diode temperature, case to heat-sink temperature difference, voltage drain to source, current drain to source, voltage gate to source, power, and estimated thermal resistance.

14. The electronic device health prediction system of claim 12 wherein the testing module is further configured to record a median value for each of the dimensions based upon measurements obtained from a plurality of times when the subject device is on.

15. The electronic device health prediction system of claim 14 wherein the testing module is further configured to input the median value for each of the dimensions to produce a two dimensional space.

16. The electronic device health prediction system of claim 11 wherein the threshold distance comprises a Mahalanobis distance.

17. The electronic device health prediction system of claim 11 wherein the auto-encoder is further configured to:
utilize a trained model learned in a training phase to encode features of the other devices and associate the features of the other devices; and
associate the features of the other devices to a cluster found in the training phase based upon respective distances in a plurality of threshold distances.

18. The electronic device health prediction system of claim 17 wherein the testing module is further configured to determine which of the device clusters the subject device is most similar, based upon respective distances of the subject device to each of the device clusters within the reduced feature set.

19. The electronic device health prediction system of claim 17 further comprising a training module configured to cluster training set features observed in the encoded features according to K-means clustering.

20. An electronic device health prediction system comprising:
non-transitory memory and a processor coupled to the non-transitory memory;
an artificial neural network comprising:
an auto-encoder configured to utilize the processor to:
receive a multi-dimensional input feature set of three or more dimensions;
record a median value for each of the dimensions based upon a plurality of times when the subject device is on;
encode the input feature set into a reduced feature set;
decode the reduced feature set; and
read the reduced feature set as output; and
a testing module configured to:
encode features of a subject device and other devices, wherein at least one of the other devices is designated as a healthy device;
associate the features of the other devices with a healthy device cluster based on a Mahalanobis distance;
determine which of the other device clusters the subject device is most similar, based upon respective distances of the subject device to each of the device clusters within the reduced feature set; and
associate the features of the subject device with the healthy device cluster, wherein the subject device having a Mahalanobis distance exceeding a threshold distance from the cluster of healthy devices is flagged as faulty.
